(19) United States
(12) Patent Application Publication
(10) Pub. No.: US 2015/0200631 A1
(43) Pub. Date: Jul. 16, 2015

(54) DUAL-BAND DOHERTY COMBINER/IMPEDANCE TRANSFORMER CIRCUIT AND DOHERTY POWER AMPLIFIER INCLUDING THE SAME

(71) Applicant: Alcatel-Lucent Canada Inc., Ottawa (CA)

(72) Inventor: Noureddine OUTALEB, Ottawa (CA)

(73) Assignee: ALCATEL-LUCENT CANADA INC., Ottawa (CA)

(21) Appl. No.: 14/155,879

(22) Filed: Jan. 15, 2014

(51) Int. Cl. H03F 1/02; H03F 3/21; H03F 3/19

(52) U.S. Cl. CPC H03F 1/0288; H03F 3/19; H03F 3/21; H03F 2200/255; H03F 2200/451; H03F 2203/21139

(57) ABSTRACT

A dual band Doherty component circuit of a dual band Doherty amplifier, which is configured to operate at first and second operating frequencies, includes a Doherty combiner circuit, the Doherty combiner circuit including, a first input node configured to receive a first output, a combining node configured to receive a second output and combine the first output with the second output, the first output being an output of a main amplifier stage of the Doherty amplifier, the second output being an output of a peak amplifier stage of the Doherty amplifier; and a broadband impedance transformer circuit including, first, second, and third lines, the first and second lines being electrically coupled to one another, the first and third lines being connected to an input of the impedance transformer circuit, the second line being connected to an output of the impedance transformer circuit.

### BACKGROUND

Wireless communication standards are changing rapidly in order to respond to the never decreasing thirst of the consumers who continuously seek the ability to exchange high volumes of data at higher data rates, and at lower cost. Network operators may find it challenging to handle the cost associated with continuously trying to adapt their already deployed sites with the new standards in order to satisfy the desires of the consumers. Base station vendors face similar challenges as their wireless product strategy is affected by the continuous standard changes. Multi-standard and multi-band radio base station technology represents one solution that may reduce the cost of these products as well as the cost of the future wireless network infrastructures. The software defined radio appears to be the leading technology that will drive the future multi-standard base station. Another enabling component for these converged products is the multi-band transceiver. More specifically, a power amplifier included in a multi-band transceiver may be required to operate in a multitude of frequency bands. In addition, in order to keep the base station operating expenses (OPEX) low, the broadband/multiband power amplifiers should be highly efficient. This requirement for high efficiency represents another challenge for network operators and base station vendors.

### SUMMARY

According to at least one example embodiment, a dual band Doherty component circuit of a dual band Doherty amplifier, which is configured to operate at first and second operating frequencies, includes a Doherty combiner circuit and a broadband impedance transformer circuit. The Doherty combiner circuit includes a first input node configured to receive a first output, a combining node configured to receive a second output and combine the first output with the second output, the first output being an output of a main amplifier stage of the Doherty amplifier, the second output being an output of a peak amplifier stage of the Doherty amplifier. The broadband impedance transformer circuit includes first, second, and third lines, the first and second lines being electrically coupled to one another, the first and third lines being connected to an input of the impedance transformer circuit, the second line being connected to an output of the impedance transformer circuit, the first and second lines being interconnected via the third line, the first, second and third lines each having an electrical length of a quarter wavelength, the input node of the broadband impedance transformer circuit being connected to the combining node of the Doherty combiner circuit.

According to at least one example embodiment, the Doherty component circuit is configured such that, at both the first and second operating frequencies, during a power back-off operating state of the Doherty amplifier, if an impedance at the first input node is 50Ω, the Doherty combiner circuit transforms the impedance at the first input node to 12.5Ω at the combining node, and the broadband impedance transformer circuit transforms the impedance at the combining node to 50Ω at the output of the broadband impedance transformer circuit.

According to at least one example embodiment, the Doherty component circuit is a three-port component, the three ports including, the first input node as a first input port, the combining node as a second input port, and the output node of the broadband impedance transformer circuit as an output port.

According to at least one example embodiment, the Doherty combiner circuit has a pi-type structure.

According to at least one example embodiment, the Doherty combiner circuit and the broadband impedance transformer circuit are each implemented using microstrip technology.

According to at least one example embodiment, the Doherty combiner circuit and the broadband impedance transformer circuit are each implemented using one or more of stripline technologies, coplanar technologies, waveguide technologies, and coax line technologies.

According to at least one example embodiment, a dual band Doherty amplifier includes a main amplifier configured to amplify a first signal at first and second frequencies; a peak amplifier configured to amplify a second signal at the first and second frequencies; and a dual band Doherty component circuit configured to receive the first signal from the main amplifier, receive the second signal from the peak amplifier, combine the first and second signals, and output the combined signal. The Doherty component circuit includes a Doherty combiner circuit and a broadband impedance transformer circuit. The Doherty combiner circuit includes a first input node configured to receive the first signal from main amplifier, and a combining node configured to receive the second signal from the peak amplifier and combine the first signal with the second signal. The broadband transformer circuit includes first, second, and third lines, the first and second lines being electrically coupled to one another, the first and third lines being connected to an input of the broadband transformer circuit, the second line being connected to an output of the broadband transformer circuit, the first and second lines being interconnected via the third line, the first, second and third lines each having an electrical length of a quarter wavelength, the input node of the broadband transformer circuit being connected to the combining node of the Doherty combiner circuit.

According to at least one example embodiment, the Doherty component circuit is configured such that, at both the first and second operating frequencies, during a power back-off operating state of the Doherty amplifier, if an impedance at the first input node is 50Ω, the Doherty combiner circuit transforms the impedance at the first input node to 12.5Ω at the combining node, and the impedance transformer circuit transforms the impedance at the combining node to 50Ω at the output of the impedance transformer circuit.

According to at least one example embodiment, the Doherty combiner circuit has a pi-type structure.

According to at least one example embodiment, the Doherty combiner circuit and the broadband impedance transformer circuit are each implemented using microstrip technology.

According to at least one example embodiment, the Doherty combiner circuit and the broadband impedance transformer circuit are each implemented using one or more of stripline technologies, coplanar technologies, waveguide technologies, and coax line technologies.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of the present invention, and wherein:

FIG. 1A illustrates a Doherty amplifier structure according to at least one example embodiment.

FIG. 1B illustrates a Doherty amplifier structure including a digital signal processor (DSP) according to at least one example embodiment.

FIG. 1C illustrates a Doherty amplifier structure according to at least one example embodiment.

FIG. 2 illustrates the structure and operation of a dual-band Doherty combiner at power back-off, when peak stage is off, according to at least one example embodiment.

FIG. 3 illustrates the operation of a dual-band Doherty combiner at peak power, when a peak stage is on, according to at least one example embodiment.

FIG. 4A illustrates the structure and operation of a broadband Doherty impedance transformer according to at least one example embodiment.

FIG. 4B illustrates a more detailed schematic of the broadband Doherty impedance transformer of FIG. 4A.

FIG. 5 illustrates the structure and operation of a dual-band Doherty combiner/impedance transformer.

### DETAILED DESCRIPTION OF EXAMPLE EMBODIMENTS

Various example embodiments will now be described more fully with reference to the accompanying drawings. Like elements on the drawings are labeled by like reference numerals.

As used herein, the singular forms “a”, “an”, and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Example embodiment will now be described with reference to the attached figures. Various structures, systems and devices are schematically depicted in the drawings for purposes of explanation only and so as not to obscure the present invention with details that are well known to those skilled in the art. Nevertheless, the attached drawings are included to describe and explain example embodiments. The words and phrases used herein should be understood and interpreted to have a meaning consistent with the understanding of those words and phrases by those skilled in the relevant art. To the extent that a term or phrase is intended to have a special meaning, i.e., a meaning other than that understood by skilled artisans, such a special definition will be expressly set forth in the specification that directly and unequivocally provides the special definition for the term or phrase.

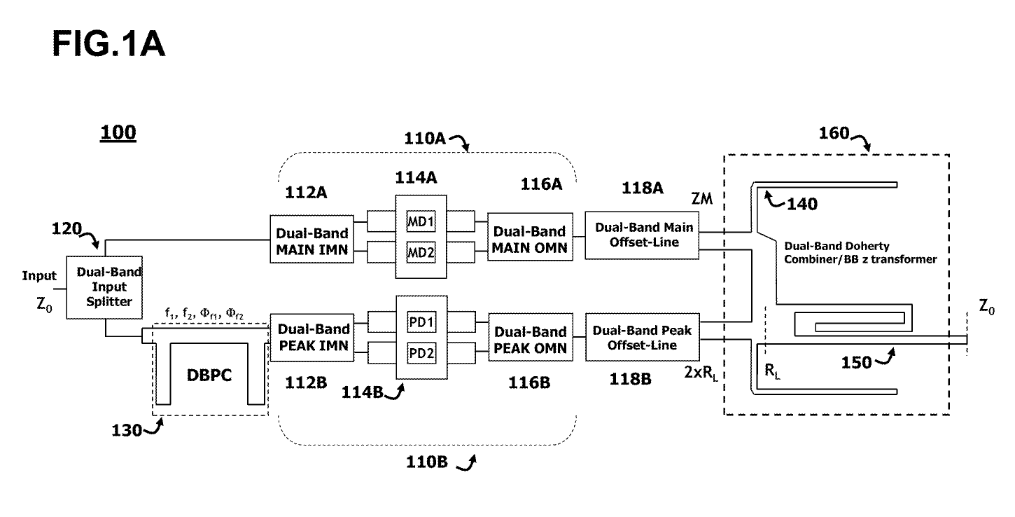

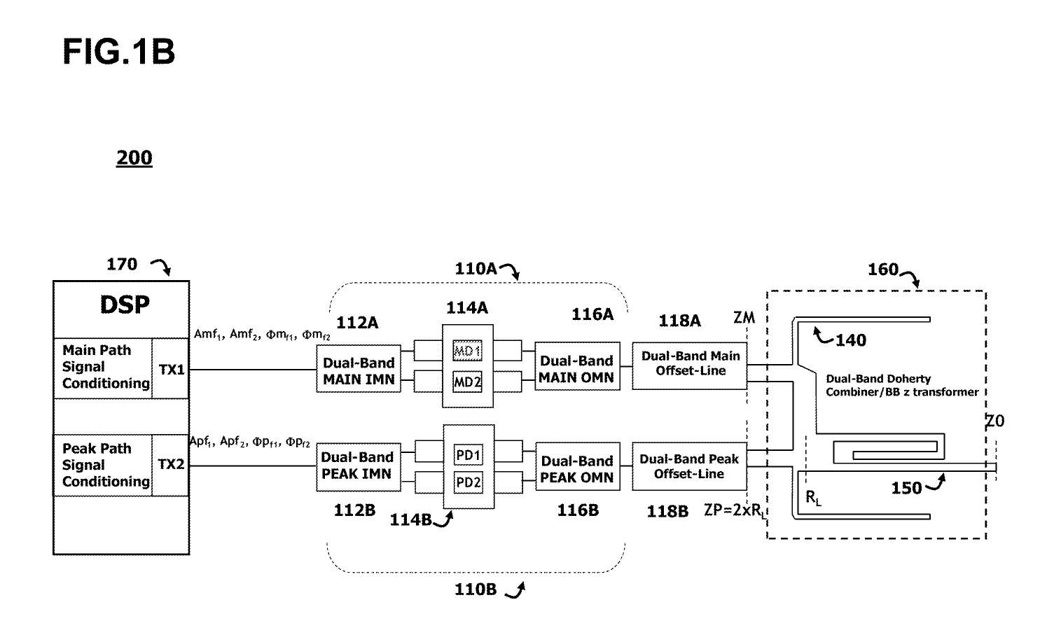

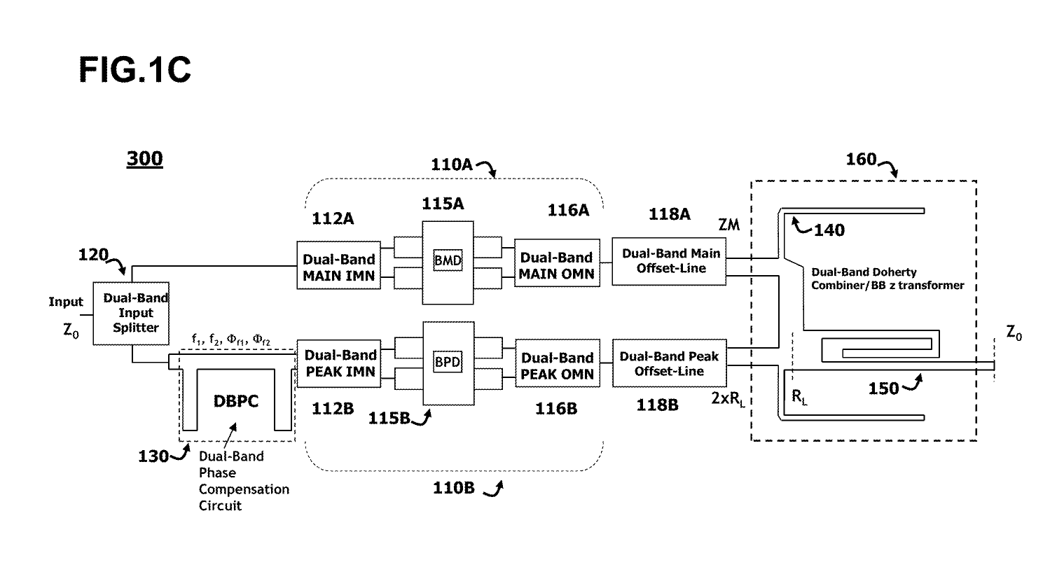

Doherty amplifiers that are used in multi-band applications, for example dual-band Doherty impedance transformers, may be required to perform amplification over two different frequencies. The dual-band Doherty amplifier according to at least one example embodiment may perform amplification while still exhibiting Doherty behavior, even when the two different frequencies are substantially separated from one another. As will be discussed in greater detail below, FIG. 1A illustrates an example of such a Doherty amplifier in which both the main and peak power amplifiers are implemented by hybrid packaged power devices. Example implementations of dual-band Doherty amplifiers are discussed in U.S. application Ser. No. 13/946,369, the entire contents of which are incorporated herein by reference

Example embodiments provide a dual band Doherty combiner/impedance transformer circuit for use with dual-band Doherty amplifiers. The dual band Doherty combiner/impedance transformer circuit according to example embodiments may increase the robustness of the Doherty amplifiers that include the dual band Doherty combiner/impedance transformer circuit, while maintaining a compact form.

Doherty amplifiers including the dual band Doherty combiner/impedance transformer of the present invention may be embodied in a base station in a wireless communication system that provides wireless connectivity to a number of end users. The Doherty amplifiers may amplify signals to be transmitted to the end users. Further, the Doherty amplifiers of the present invention may be embodied in other types of devices such as W-CDMA, UMTS, LTE or WiMAX base stations, base transceiver stations, base station routers, WiFi access points, or any other device that provides the radio baseband functions for data and/or voice connectivity between a network and one or more end users. The end users may include but are not limited to end user (EU) equipment, fixed or mobile subscriber units, receivers, cellular telephones, personal digital assistants (PDA), personal computers, or any other type of user device capable of operating in a wireless environment.

A Doherty amplifier according to example embodiments is a multi-band power amplifier having a dual band Doherty combiner/impedance transformer circuit which includes both a pi-section dual band impedance transformer (i.e., Doherty inverter/combiner) and a broadband impedance transformer. The dual band Doherty combiner/impedance transformer circuit according to example embodiments allows for the provision of desired load impedances to the main stage of the Doherty amplified at any dual-band frequencies while presenting the load impedance necessary to match an output circulator or an input of an antenna, for example, 50 ohms. These embodiments are discussed with reference to FIGS. 1-5 of the present application.

FIG. 1A illustrates a structure of a Doherty amplifier 100 according to at least one example embodiment.

The Doherty amplifier 100 includes a dual-band input splitter 120 to receive and split input signal into a first signal and a second signal, a dual-band impedance transformer/phase compensator circuit 130 for shifting a phase of the second signal, a main amplifier 110A for amplifying the first signal, a peak amplifier 110B for selectively amplifying the second signal, and a dual-band Doherty combiner/impedance transformer circuit 160. The dual-band Doherty combiner/impedance transformer circuit 160 includes a dual-band Doherty combiner/inverter 140 for combining the output of the main amplifier 110A and the peak amplifier 110B, and a broadband impedance transformer 150 configured to perform the impedance transformation of the combining node load R_{L} impedance to output load impedance of the Doherty Z₀.

The dual-band input splitter 120 generally divides the input signal into first and second signals and is capable of operating at two different frequencies. The dual-band input splitter 120 may have the structure of any known dual-band Doherty power splitter. The dual-band input splitter 120 may receive an input signal. The dual-band input splitter 120 may provide the first signal through a connection to an input of the main amplifier 110A, and provide the second signal though a connection to an input of the peak amplifier 110B via the impedance transformer/phase compensator 130.

The dual-band input splitter 120 performs the input signal splitting in the dual frequency band of interest. The 2 dual-band input splitter output terminals which are connected to the main amplifier 110A and the peak amplifier 110B can be 50Ω or any other real impedance R that facilitates the designs of these input dual-band matching networks. The dual-band impedance transformer/phase compensator 130 may impedance transform and phase shift the second signal that will drive the peak amplifier 110B.

The impedance transformer/phase compensator 130 is configured to transform the output impedance of the dual-band splitter 120 to 50Ω, or any other arbitrary real impedance R that eases the design of the dual-band peak input matching network 112B, at both frequencies f1 and f2, respectively. It is configured to compensate for the phase change phases Φ_{f1} and Φ_{f2} introduced by the dual-band Doherty combiner/inverter 140 at frequencies f1 and f2, respectively. The impedance transformer/phase compensator 130 may be based, for example, on a three transmission line arrangement in a “pi” structure as is illustrated in FIG. 1A. Though FIG. 1A illustrates an example in which the impedance transformer/phase compensator 130 may have the “pi” structure, the dual-band impedance transformer/phase compensator 130 may have the structure of any known dual-band Doherty impedance transformer/phase compensator.

Further, in embodiments where dual-band digital Doherty is used, the impedance transformer/phase compensator 130 may be omitted. For example, FIG. 1B illustrates a Doherty amplifier structure including a digital signal processor (DSP) according to at least one example embodiment.

FIG. 1B shows the Doherty amplifier 200 including a DSP 170 for implementing dual-band digital Doherty. As is illustrated in FIG. 1B, when the DSP 170 is used, the impedance transformer/phase compensator 130 may be omitted. In the embodiment illustrated in FIG. 1B, the phase compensation and the amplitude match between the main and the peak paths are provided through digital processing with using signal conditioning. The DSP 170 includes a first output TX1 that outputs signals having amplitudes Amf₁ and Amf₂ and phase shifts Φm_{f1} and Φm_{f2o} at first and second frequencies, respectively, to the main amplifier 110A, The DSP 170 includes a second output TX2 that outputs signals having amplitudes Apf₁ and Apf₂ and phase shifts Φp_{f1} and Φp_{f2}, at first and second frequencies, respectively, to the peak amplifier 110B. The amplitudes Amf₁ and Amf₂ are digitally and accurately adjusted, using DSP 170 TX1, at the dual band frequencies f1 and f2, on the main path, to compensate for any amplitude mismatch between the main and the peak paths, that might be related the device gain variation at the 2 frequencies. The phase mismatch compensation is also introduced on the main path, through adjustments the TX1 output signal phase shifts Φm_{f1} and Φm_{f2o} at both frequencies f1 and f2. Similarly, the amplitudes Apf₁ and Apf₂ are digitally and accurately adjusted, using DSP 170 TX2, at the dual band frequencies f1 and f2, on the peak path, to compensate for any amplitude mismatch between the main and the peak paths, that might be related the device gain variation at the 2 frequencies. The phase mismatch compensation is also introduced on the peak path, through adjustments of the TX1 output signal phase shifts Φm_{f1} and Φm_{f2o} at both frequencies f1 and f2, to compensate for the phase shift introduced by the dual-band output Doherty combiner/inverter 140, in one hand, and in the other hand to accurately adjust any residual phase mismatch between the main and the peak path. Because of the accurate main signal and peak signal amplitude and phase control, it is expected that the Dual-band Doherty performance will be improved further with using DSP 170.

The first and second signals are amplified, respectively, by the main amplifier 110A, or the combination of the main amplifier 110A and the peak amplifier 110B, as discussed below.

For example, the peak amplifier 110B is selectively operable to operate at selected times in combination with the main amplifier 110A. That is, the peak amplifier 110B may be kept off until power requirements call for a higher power output from the whole Doherty power amplifier 100, at which time the peak amplifier 110B is turned on and operates to contribute to the output power increase of the Doherty power amplifier 100. In other words, the peak amplifier 110B amplifies the second signal at higher peak envelopes where the signal strength of the second signal is above a threshold level. The term “selectively operable” indicates the amplifier operational state changes in response to the input signal. Otherwise, if the signal strength of the second signal is below the threshold level, the peak amplifier 110B is turned OFF and only the main amplifier 110A operates to amplify the first signal.

The main amplifier 110A includes a dual band main input matching network (IMN) 112A, a main hybrid packaged power device 114A and a dual band main output matching network (OMN) 116A. Signals are input to the main amplifier 110A through the dual band main input matching network (IMN) 112A, and output from the main amplifier 110A through the output matching network (OMN) 116A. According to at least one example embodiment, the main hybrid packaged power device 114A includes two dies, a first main die MD1 and a second main die MD2. The first and second main dies MD1 and MD2 include power transistors configured to operate at different frequencies, respectively. A first output of the dual-band main IMN 112A is connected to an input of the first main die MD1, and an output of the first main die MD1 is connected to a first input of the dual-band main OMN 116A. A second output of the dual-band main IMN 112A is connected to an input of the second main die MD2, and an output of the second main die MD2 is connected to a second input of the dual-band main OMN 116A. The dual-band main input matching network IMN 112A transforms the 2 complex input impedances Zᵢₘ₁=aᵢₘ₁±jbᵢₘ₁ and Zᵢₘ₂=aᵢₘ₂±jbᵢₘ₂ presented by the dies MD1 and MD2, respectively, to an intermediate real impedance R₀. The real impedance R₀ can be 50Ω or any intermediary value that eases the design of the dual-band matching network IMN 112A. The dual band main OMN 116A transforms the 2 complex output impedances Zₒₘ₁=aₒₘ₁±jbₒₘ₁ and Zₒₘ₂=aₒₘ₂±jbₒₘ₂ presented by the dies MD1 and MD2, respectively, to a real impedance 2×Rₘ at power back-off (peak stage is off) and to a real impedance Rₘ at peak power (peak running at full power). The real impedance Rₘ can be 50Ω or any intermediary value that ease the design of the Dual-band output matching network OMN 116A.

As used herein, a variable using the format ‘Zx’ denotes an impedance x, ‘ax’ denotes a resistance component of a corresponding impedance Zx, ‘bx’ denotes a reactance component of a corresponding impedance Zx, and ‘j’ is the imaginary unit.

The peak amplifier 110B includes a structure similar to that discussed above with respect to the main amplifier 110A. The peak amplifier 110B includes a dual band peak input matching network (IMN) 112B, a peak hybrid packaged power device 114B and a dual band main output matching network (OMN) 116B. Signals are input to the peak amplifier 110B through the dual band peak input matching network (IMN) 112B, and output from the peak amplifier 110B through the output matching network (OMN) 116B. As will be discussed in greater detail below, the peak hybrid packaged power device 114B includes two dies, a first peak die PD1 and a second peak die PD2. The first and second peak dies PD1 and PD2 include power transistors configured to operate at different frequencies, respectively. A first output of the dual-band peak IMN 112B is connected to an input of the first peak die PD1, and an output of the first peak die PD1 is connected to a first input of the dual-band peak OMN 116B. A second output of the dual-band peak IMN 112B is connected to an input of the second peak die PD2, and an output of the second peak die PD2 is connected to a second input of the dual-band peak OMN 116B. The dual-band peak IMN 112B transforms the 2 complex input impedances Zᵢₚ₁=aᵢₚ₁±jbᵢₚ₁ and Zᵢₚ₂=aᵢₚ₂±jbᵢₚ₂ presented by the dies PD1 and PD2, respectively, to an intermediate real impedance R₀. The real impedance R₀ can be, for example, 50Ω or any intermediary value that eases the design of the Dual-band matching network IMN 112B. The dual band peak OMN 116B transforms the 2 complex output impedances Zₒₚ₁=aₒₚ₁±jbₒₚ₁ and Zₒₚ₂=aₒₚ₂±jbₒₚ₂ presented by the dies PD1 and PD2, respectively, to an intermediate real impedance R₀. The real impedance R₀ can be, for example, 50Ω or any intermediary value that ease the design of the Dual-band matching network OMN 116B.

FIG. 1C illustrates a Doherty amplifier 300 according to at least one example embodiment. The Doherty amplifier 300 differs from the Doherty amplifier 100 illustrated in FIG. 1A by including a main broadband power device 115A and a peak broadband power device 115B, that include a single broadband main die BMD and a single broadband peak die BPD, respectively.

For example, with respected to the Doherty amplifier 300, the main amplifier 110A includes a dual band main input matching network (IMN) 112A, the broadband power device 115A and a dual band main output matching network (OMN) 116A. Signals are input to the main amplifier 110A through the dual band main input matching network (IMN) 112A, and output from the main amplifier 110A through the output matching network (OMN) 116A, and the main broadband power device 115A includes only one broadband die BMD which is configured to operate in a broadband RF bandwidth that covers the dual frequency bands of interest. A first output of the dual-band main IMN 112A is connected to an input of the broadband die, and an output of the broadband die is connected to a first input of the dual-band main OMN 116A. A second output of the dual-band main IMN 112A is connected to an input of the broadband die, and an output of the broadband die is connected to a second input of the dual-band main OMN 116A. The dual-band main input matching network IMN 112A transforms the 2 complex input impedances Zᵢₘ₁=aᵢₘ₁±jbᵢₘ₁ and Zᵢₘ₂=aᵢₘ₂±jbᵢₘ₂ presented by the broadband die, to an intermediate real impedance R₀. The real impedance R₀ can be 50Ω or any intermediary value that eases the design of the dual-band matching network IMN 112A. The dual band main OMN 116A transforms the 2 complex output impedances Zₒₘ₁=aₒₘ₁±jbₒₘ₁ and Zₒₘ₂=aₒₘ₂±jbₒₘ₂ presented by the broadband die, to a real impedance 2×Rₘ at power back-off (peak stage is off) and to a real impedance Rₘ at peak power (peak running at full power). The real impedance Rₘ can be 50Ω or any intermediary value that ease the design of the Dual-band output matching network OMN 116A.

Similarly for the peak amplifier 110B, in another embodiment the peak amplifier 110B includes a structure similar to that discussed above with respect to the main amplifier 110A, where the peak amplifier 110B includes a dual band peak input matching network (IMN) 112B, the peak broadband power device 115B and a dual band main output matching network (OMN) 116B. Signals are input to the peak amplifier 110B through the dual band peak input matching network (IMN) 112B, and output from the peak amplifier 110B through the output matching network (OMN) 116B. Further, the peak broadband power device 115B includes only one broadband die BPD which is configured to operate in a broadband RF bandwidth that covers the dual frequency bands of interest. A first output of the dual-band peak IMN 112B is connected to an input of the broadband die, and an output of the broadband die is connected to the input of the dual-band peak OMN 116B. A second output of the dual-band peak IMN 112B is connected to the broadband die, and an output of the broadband die is connected to a second input of the dual-band peak OMN 116B. The dual-band peak IMN 112B transforms the 2 complex input impedances Zᵢₚ₁=aᵢₚ₁±jbᵢₚ₁ and Zᵢₚ₂=aᵢₚ₂±jbᵢₚ₂ presented by the broadband die, to an intermediate real impedance R₀. The real impedance R₀ can be, for example, 50Ω or any intermediary value that eases the design of the Dual-band matching network IMN 112B. The dual band peak OMN 116B transforms the 2 complex output impedances Zₒₚ₁=aₒₚ₁±jbₒₚ₁ and Zₒₚ₂=aₒₚ₂±jbₒₚ₂ presented by the broadband die, to an intermediate real impedance R₀. The real impedance R₀ can be, for example, 50Ω or any intermediary value that ease the design of the Dual-band matching network OMN 116B.

As depicted in FIGS. 1A-1C, according to at least some example embodiments, the outputs of the main amplifier 110A and the peak amplifier 110B may be respectively connected to a dual-band main offset line 118A and a dual-band peak offset line 118B. The dual-band main offset line may receive the first signal and provide the first signal to a first input of the dual band Doherty combiner/impedance transformer circuit 160. The dual-band peak offset line may receive the second signal and provide the second signal to a second input of the dual band Doherty combiner/impedance transformer circuit 160.

Detailed example structures and manners of operation for the Doherty amplifier 100, including, for example, the main amplifier 110A, peak amplifier 110B, dual-band main offset line, and a dual-band peak offset line are, provided in U.S. application Ser. No. 13/946,369, which, as is noted above, is incorporated in its entirety into the present application.

As is discussed above, the dual-band Doherty combiner/impedance transformer circuit 160 includes a dual-band Doherty combiner/inverter 140 and a broadband impedance transformer 150. In accordance with the known Doherty operating principle, the output impedance of the main amplifier 110A is the impedance ZM, which is modulated as a result of the variation of the current of the peak amplifier 110B in conjunction with the dual-band Doherty combiner/inverter 140. The dual-band Doherty combiner/inverter 140 receives the first signal from the dual-band main offset line 118A, and receives the second signal from the dual-band peak offset line 118B. The dual-band Doherty combiner/inverter 140 serves as an impedance inverter and, in accordance with known methods, is configured to act as a dual-band impedance inverter that that ensures impedance transformations that include −90 degrees phase shifts at the dual-band frequencies f1 and f2 at which the dual-band Doherty amplifier 100 is configured to operate. In the example illustrated in FIG. 1A, the dual-band Doherty combiner/inverter 140 of the dual band Doherty combiner/impedance transformer circuit 160 is implemented using the known microstrip line “pi” structure. In another embodiment, the dual-band Doherty combiner/inverter 140 of the dual band Doherty combiner/impedance transformer circuit 160 can be implemented using one or more of stripline technologies, coplanar technologies, waveguide technologies, coax line technologies, and any existing transmission line technologies including, for example, transmission line technologies using the known ‘pi’ structure.

The dual-band Doherty combiner/inverter 140 is connected to an output of the dual-band Doherty amplifier 100 via the broadband impedance transformer 150. In accordance with known methods, the dual-band impedance transformer is configured to transform the output load Z₀ of the dual-band Doherty amplifier 100 to the combining node load R_{L} at the output of the dual-band Doherty combiner/inverter 140.

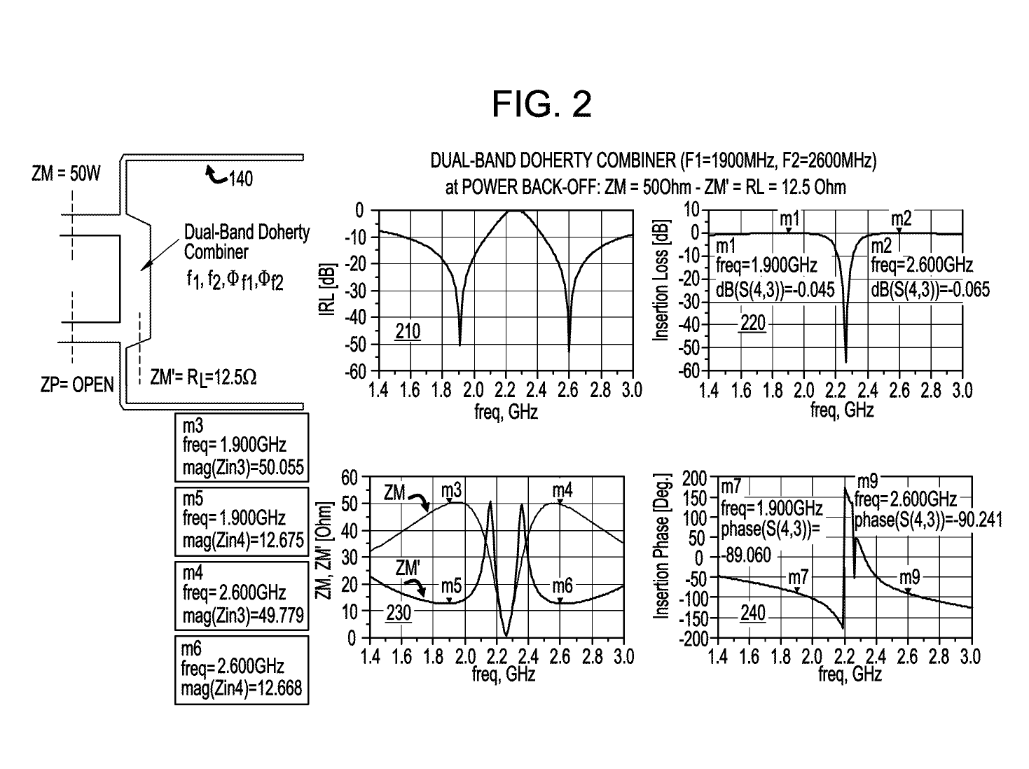

The structure and operation of the dual-band Doherty combiner/impedance transformer 160 will now be discussed in greater detail below with reference to FIGS. 2-5. In the examples discussed below with reference to FIGS. 2-5, the dual-band Doherty combiner/impedance transformer 160 is configured to operate at a first frequency f1=1900 MHz and a second frequency f2=2600 MHz. Further, in the examples discussed below with reference to FIGS. 2-5, the desired output impedance, Z₀, is 50Ω, the desired modulated impedance, ZM, at power back-off is 50Ω, the desired modulated impedance, ZM, at peak power is 25Ω, the desired combining node impedance, R_{L}, at power back-off is 12.5Ω, and the desired combining node impedance, R_{L}, at peak power is the resulted impedance of the ZM′ and ZP which are the main output transformed impedance at the combining node side and the peak output impedance, at peak power, respectively. Hence, the resulted combining node impedance R_{L} is also 12.5Ω at the peak power as well.

FIG. 2 illustrates the structure and operation of a dual-band Doherty combiner at power back-off, when peak stage is off, according to at least one example embodiment.

FIG. 2 includes the input return loss (IRL) graph 210 which plots the IRL of the dual band Doherty combiner/inverter 140 (in decibels) over frequency (in gigahertz) at power back-off; the insertion loss graph 220 which plots the insertion loss of the dual band Doherty combiner/inverter 140 (in decibels) over frequency (in gigahertz) at power back-off; the ZM and ZM′ impedance graph 230 which plots both the modulated impedance of the dual band Doherty combiner/inverter 140, ZM (in ohms), and the combining node impedance of the dual band Doherty combiner/inverter 140, ZM′=R_{L} (in ohms), over frequency (in gigahertz) at power back-off; and an insertion phase graph 240 which plots an insertion phase of −90 degrees achieved at the dual band operating frequencies f1 and f2 of the Doherty combiner/inverter 140 (in degrees) over frequency (in gigahertz). Graphs 210˜240 represent the results of circuit simulations for the dual band Doherty combiner/inverter 140.

Referring to IRL graph 210, the dual-band Doherty combiner/inverter 140 exhibits desirably low IRL for both first and second operating frequencies f1 and f2. Referring to power back-off insertion loss graph 220, according to at least one example embodiment, the dual-band Doherty combiner/inverter 140 exhibits a desirable minimum insertion loss lower than 0.1 dB for both first and second operating frequencies f1 and f2, as is illustrated by graph markers m1 and m2. Referring to the impedance graph 230, while operating in power back-off mode, the dual-band Doherty combiner/inverter 140 transforms the modulated impedance ZM of 50Ω at the node of the Doherty combiner/inverter 140 that connects to the main amplifier 110A to the combining node impedance ZM′=RL of 12.5Ω for both first and second operating frequencies f1 and f2, as is illustrated by graph markers m3-m6. Further, referring to insertion phase graph 240, the insertion phase of the dual-band Doherty combiner/inverter 140 is at −90° for both first and second operating frequencies f1 and f2, as is illustrated by graph markers m7 and m9.

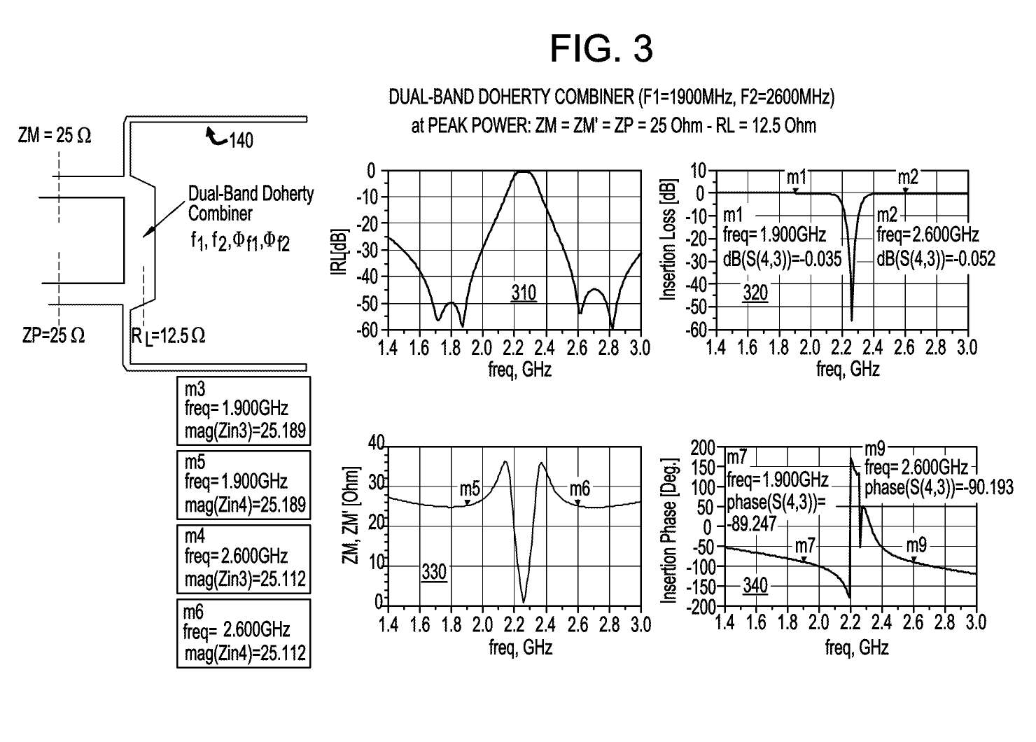

FIG. 3 illustrates the operation of a dual-band Doherty combiner at peak power, when a peak stage is on, according to at least one example embodiment.

FIG. 3 includes the input return loss (IRL) graph 310 which plots the IRL of the dual band Doherty combiner/inverter 140 (in decibels) over frequency (in gigahertz) at peak power; the insertion loss graph 320 which plots the insertion loss of the dual band Doherty combiner/inverter 140 (in decibels) over frequency (in gigahertz) at peak power; the ZM, ZM′ impedance graph 330 which plots both the modulated impedance of the dual band Doherty combiner/inverter 140, ZM (in ohms), and ZM′ (in ohms) which is the transformed impedance of ZM located at the output port of the dual band Doherty combiner/inverter 140. The transformed impedance ZM′ in conjunction with the peak stage load impedance at peak power ZP will combine to result the combining node RL of 12.5Ω, over frequency (in gigahertz) at peak power; and an insertion phase graph 340 which plots an insertion phase of the dual band Doherty combiner/inverter 140 (in degrees) over frequency (in gigahertz). Graphs 310˜340 represent the results of circuit simulations, at peak power mode, for the dual band Doherty combiner/inverter 140.

Referring to the IRL graph 310, the dual-band Doherty combiner/inverter 140 exhibits desirably low IRL for both first and second operating frequencies f1 and f2, at peak power. Referring to insertion loss graph 320, while operating in peak power mode, the dual-band Doherty combiner/inverter 140 exhibits a desirable minimum insertion lower than 0.1 dB for both first and second operating frequencies f1 and f2, as is illustrated by graph markers m1 and m2. Referring to input/output graph 330, while operating in peak power mode, the dual-band Doherty combiner/inverter 140 transforms the modulated impedance ZM of 25Ω at the node of the Doherty combiner/inverter 140 that connects to the main amplifier 110A to ZM′ (in ohms) which is the transformed impedance of ZM located at the output port of the dual band Doherty combiner/inverter 140. The transformed impedance ZM′ in conjunction with the peak stage load impedance at peak power ZP will combine to result into the combining node RL of 12.5Ω for both first and second operating frequencies f1 and f2, as is illustrated by graph markers m3-m6. Further, referring to insertion phase graph 340, the insertion phase of the dual-band Doherty combiner/inverter 140 is at −90° for both first and second operating frequencies f1 and f2, as is illustrated by graph markers m7 and m9.

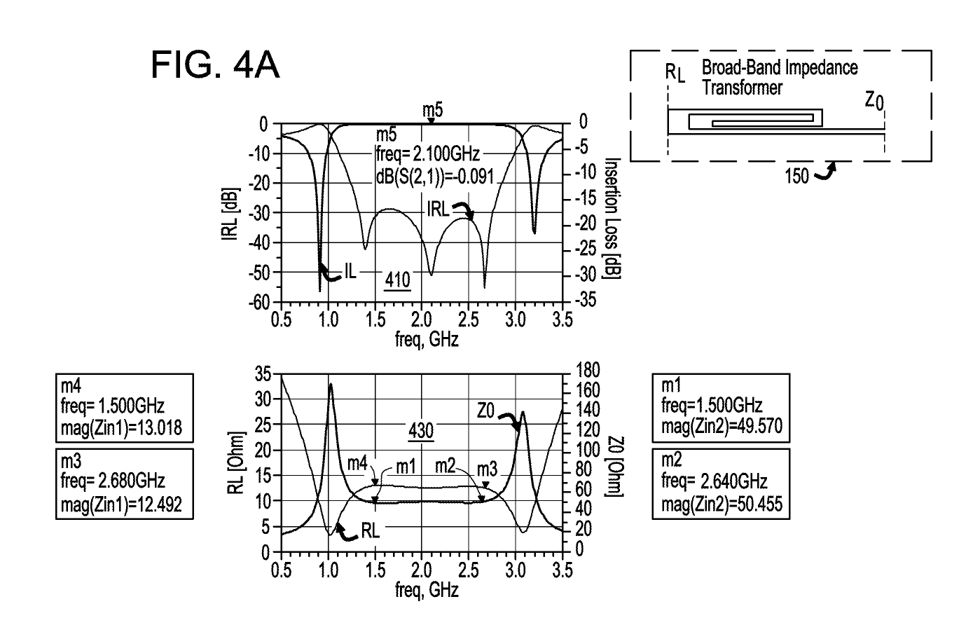

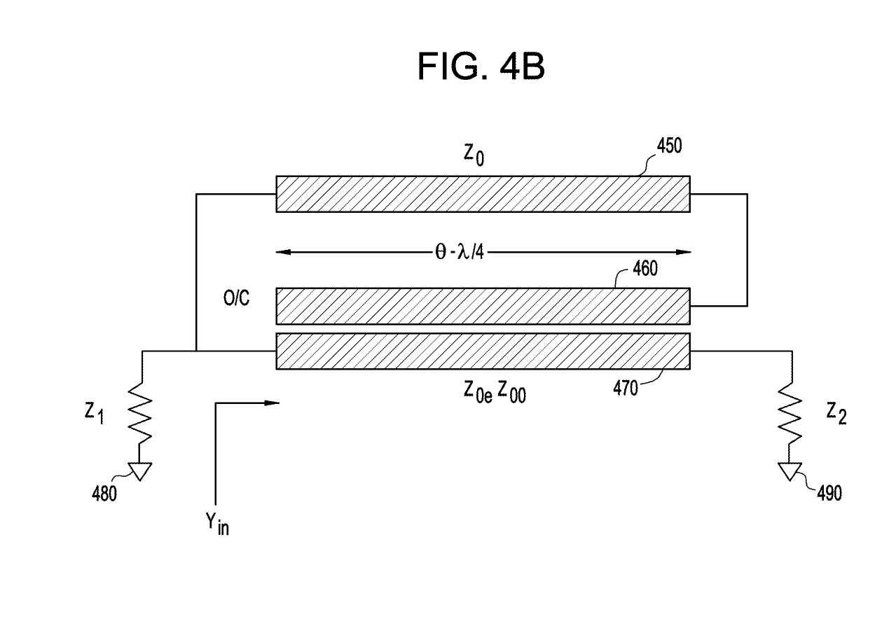

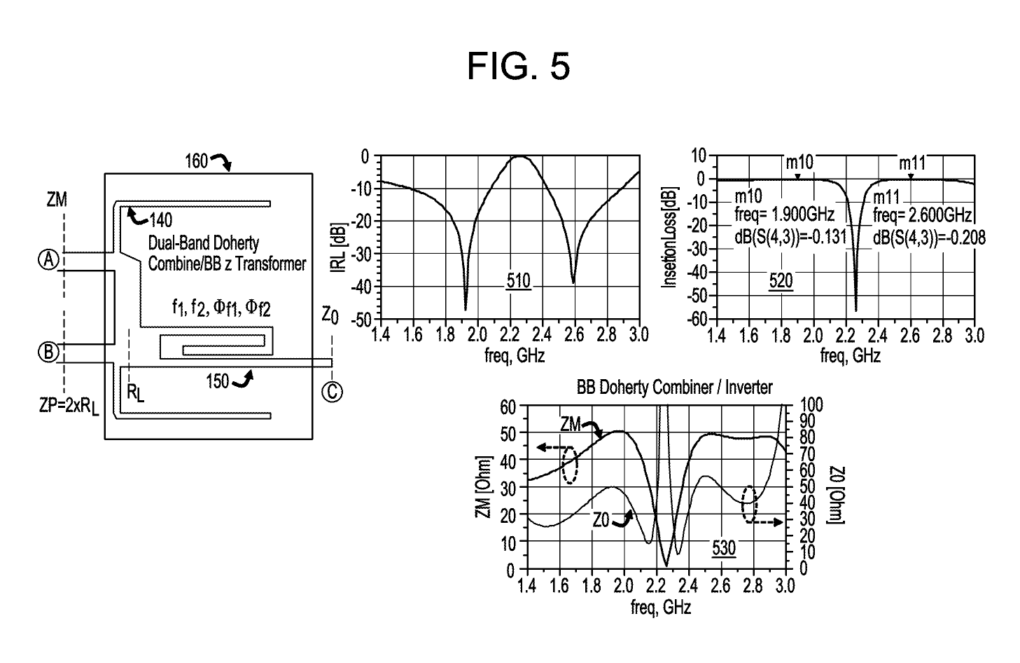

However, combiners such as the dual band Doherty combiner/inverter 140 are often associated with impedance mismatch issues at the combining node. In order to address this issue, the dual band Doherty combiner/impedance transformer circuit 160 incorporates the broadband Doherty output impedance transformer 150, which, as will be discussed in greater detail below with reference to FIG. 5, is connected to the combining node of the Doherty combiner/inverter 140 and transforms the combining node impedance, R_{L}, to the desired output node impedance Z₀. First, the structure and operation of the broadband Doherty impedance transformer 150 will be discussed in greater detail below with reference to FIGS. 4A and 4B.

FIG. 4A illustrates the structure and operation of a broad-band Doherty output impedance transformer 150 according to at least one example embodiment.

FIG. 4A includes a first graph 410 which plots both the IRL and insertion loss (IL) of the of the broadband Doherty output impedance transformer 150 (both in decibels) over frequency (in gigahertz); and a second graph 430 which plots both the combining node impedance of the broadband Doherty output impedance transformer 150, R_{L}, and the output impedance of the broadband Doherty output impedance transformer 150, Z₀, (both in ohms), over frequency (in gigahertz). Graphs 410 and 430 represent the results of circuit simulations for the broadband Doherty output impedance transformer 150.

FIG. 4B illustrates a more detailed schematic of the broadband Doherty output impedance transformer 150.

As is illustrated in FIG. 4B, the broadband Doherty impedance transformer 150 may include at least three segments. The broadband Doherty impedance transformer 150 may include an interconnecting transmission line 450. The broadband Doherty impedance transformer 150 may also include a pair of coupled lines: first line 460 second line 470. As is illustrated in FIG. 4B, one end of the first line 460 is connected to the interconnecting transmission line 450, and the other end of the first line 460 is open circuited (O/C). Further, one end of the second line 470 is connected to the interconnecting transmission line 450 and a source impedance Z₁ 480, and the other end of the second line 470 is connected to an output load impedance Z₂ 490. Accordingly, the coupled lines 460 and 470 may be connected to each other via the interconnecting transmission line 450.

The design parameters of the broadband impedance transformer 150 are the coupled lines even and odd-mode impedances Zₒₑ and Zₒₒ and the interconnecting transmission line characteristic impedance Zₒ. The electrical length, θ, of the transmission and coupled lines, 450-470, may be, for example, a quarter wavelength (i.e., or λ/4) at a center frequency of operation. In accordance with known methods, the broadband Doherty impedance transformer 150 may be configured to achieve desirable values for characteristic impedance, Zₒ, as well as even and odd-mode impedances, Zₒₑ and Zₒₒ.

Returning to FIG. 4A, as is illustrated in the first graph 410, the broadband Doherty output impedance transformer 150 demonstrates IL values which are desirably lower than 0.1 dB over a broad range of frequencies including f1 (1.9 GHz) and f2 (2.6 GHz), while also demonstrating a desirably low IRL over a broad range of frequencies including f1 and f2. Further, the broadband Doherty output impedance transformer 150 transforms the combining node impedance, RL, of 12.5Ω to the output load impedance, Z₀, of 50Ω, over a broad range of frequencies including f1 and f2.

FIG. 5 illustrates the structure and operation of a dual-band Doherty combiner/impedance transformer 160.

As is illustrated in FIGS. 1 and 5, the dual-band Doherty combiner/impedance transformer circuit 160 incorporates both the dual-band Doherty combiner/inverter 140 and the broadband Doherty impedance transformer 150 into a single circuit. The circuit is, a three-port circuit including a first node A corresponding to the modulated impedance ZM, a second node B corresponding to the load impedance ZP of the peak stage 110B, and a third node C corresponding to the output load impedance Z₀. When the Doherty combiner/impedance transformer circuit 160 is included in a Doherty amplifier circuit, the first and second nodes A and B may be connected to outputs of the main and peak amplifiers, respectively. For example, using the Doherty amplifier 100 illustrated in FIG. 1 as an example, the first node A may be connected to an output of the main amplifier 110A, the second node B may be connected to an output of the peak amplifier 110B, and the third node C may serve as an output node of the Doherty amplifier 100.

FIG. 5 includes the input return loss (IRL) graph 510 which plots the IRL of the Doherty combiner/impedance transformer circuit 160 (in decibels) over frequency (in gigahertz) when the Doherty is operating at power back-off; the insertion loss graph 520 which plots the insertion loss of the Doherty combiner/impedance transformer circuit 160 (in decibels) over frequency (in gigahertz) when the Doherty is operating at power back-off; and a graph 530 which plots both the modulated impedance ZM (in ohms) at the input of the dual band Doherty combiner/inverter 140, and the output node impedance Z₀ (in ohms) of the broadband Doherty transformer, over frequency (in gigahertz) at power back-off. Graphs 510˜530 represent the results of circuit simulations for the Doherty combiner/impedance transformer circuit 160.

Referring to IRL graph 510, the dual-band Doherty combiner/impedance transformer circuit 160 exhibits, at power back-off mode, desirably low IRL for both first and second operating frequencies f1 (1.9 GHz) and f2 (2.6 GHz). Referring to the insertion loss graph 520, the dual-band Doherty combiner/impedance transformer circuit 160 exhibits, at power back-off mode, a desirable insertion loss lower than 0.2 dB for both first and second operating frequencies f1 and f2, as is illustrated by graph markers m10 and m11. Referring to the input/output graph 530, while operating in power back-off mode, the dual-band Doherty combiner/impedance transformer circuit 160 transforms the modulated impedance ZM of 50Ω at the first node A to the output node impedance Zo of 50Ω with the second node B impedance RL set to 12.5Ω, for both first and second operating frequencies f1 and f2.

Accordingly, the dual-band Doherty combiner/impedance transformer circuit 160 including the broadband Doherty output impedance transformer 150 is capable of performing both an impedance transformation from 50Ω at the first node A to 12.5Ω at the combining node B, while also performing a transformation from 12.5Ω at the combining node B to 50Ω at the output node C. Further, as is illustrated by FIG. 5, the Doherty combiner/impedance transformer circuit 160 is capable of performing the above-referenced transformations while maintaining desirable IRL and IL values at both the first and second operating frequencies f1 and f2.

Further, the layout of the broadband Doherty output impedance transformer 150 allows the dual band Doherty combiner/impedance transformer circuit 160 to address the issue of impedance mismatch often experienced at the combining node of the dual band Doherty combiner/inverter 140 without greatly increasing the overall size of the layout of the Doherty combiner/impedance transformer circuit 160. Specifically, the broadband Doherty impedance transformer 150 is capable of performing the desired transformation between the combining node impedance R_{L} and the output impedance Z₀ using a circuit layout having a length at around only a quarter wavelength. Consequently, according to at least one example embodiment, incorporation of the broadband Doherty output impedance transformer 150 within the Doherty combiner/impedance transformer circuit 160 does not result in a large increase in a size of the layout of the Doherty combiner/impedance transformer circuit 160.

Further, the broadband characteristics of the broadband Doherty output impedance transformer 150 increase the robustness of the Doherty combiner/impedance transformer circuit 160. For example, a Doherty amplifier, including for example the Doherty amplifier 100, may be manufactured using a printing process including but not limited to, for example, a micro strip printing process. However there are limits to the accuracy with which circuits can be printed. These limitations may result in slight variations between the dual operating frequencies specified in the design of the Doherty amplifier, and the dual operating frequencies f1 and f2 actually realized by the printed Doherty amplifier circuit. As is illustrated above in FIG. 4A, the broadband Doherty output impedance transformer 150 is capable of delivering desirable behavior in terms of IL, IRL, and proper transformation of the combining node impedance RL to the output node impedance Z₀, over a broad range of operating frequencies. Consequently, the broadband Doherty output impedance transformer 150 improves the robustness of the Doherty combiner/impedance transformer circuit 160 because the broadband Doherty output impedance transformer 150 is capable of operating in a desirable manner within the Doherty combiner/impedance transformer circuit 160, even when tolerance manufacturing limitations result in unintended variations between specified dual operating frequencies and realized dual operating frequencies f1 and f2.

Variations of the example embodiments of the present invention are not to be regarded as a departure from the spirit and scope of the example embodiments of the invention, and all such variations as would be apparent to one skilled in the art are intended to be included within the scope of this invention.

What is claimed:

1. A dual band Doherty component circuit of a dual band Doherty amplifier, the dual band Doherty amplifier being configured to operate at first and second operating frequencies, the circuit comprising:
a Doherty combiner circuit, the Doherty combiner circuit including,
a first input node configured to receive a first output, and
a combining node configured to receive a second output and combine the first output with the second output, the first output being an output of a main amplifier stage of the Doherty amplifier, the second output being an output of a peak amplifier stage of the Doherty amplifier; and
a broadband impedance transformer circuit including,
first, second, and third lines, the first and second lines being electrically coupled to one another, the first and third lines being connected to an input of the impedance transformer circuit, the second line being connected to an output node of the impedance transformer circuit, the first and second lines being interconnected via the third line, the first, second and third lines each having an electrical length of a quarter wavelength, the input node of the broadband impedance transformer circuit being connected to the combining node of the Doherty combiner circuit.

2. The dual band Doherty component circuit of claim 1, wherein the Doherty component circuit is configured such that, at both the first and second operating frequencies, during a power back-off operating state of the Doherty amplifier, if an impedance at the first input node is 50Ω,
the Doherty combiner circuit transforms the impedance at the first input node to 12.5Ω at the combining node, and
the broadband impedance transformer circuit transforms the impedance at the combining node to 50Ω at the output of the broadband impedance transformer circuit.

3. The dual band Doherty component circuit of claim 1, wherein the Doherty component circuit is a three-port component, the three ports including,
the first input node as a first input port,
the combining node as a second input port, and
the output node of the broadband impedance transformer circuit as an output port.

4. The dual band Doherty component of claim 1, wherein the Doherty combiner circuit has a pi-type structure.

5. The dual band Doherty component circuit of claim 1, wherein the Doherty combiner circuit and the broadband impedance transformer circuit are each implemented using microstrip technology.

6. The dual band Doherty component circuit of claim 1, wherein the Doherty combiner circuit and the broadband impedance transformer circuit are each implemented using one or more of stripline technologies, coplanar technologies, waveguide technologies, and coax line technologies.

7. A dual band Doherty amplifier, comprising:
a main amplifier configured to amplify a first signal at first and second frequencies;
a peak amplifier configured to amplify a second signal at the first and second frequencies; and
a dual band Doherty component circuit configured to receive the first signal from the main amplifier, receive the second signal from the peak amplifier, combine the first and second signals, and output the combined signal,
the Doherty component circuit including a Doherty combiner circuit and a broadband impedance transformer circuit,
the Doherty combiner circuit including,
a first input node configured to receive the first signal from main amplifier, and
a combining node configured to receive the second signal from the peak amplifier and combine the first signal with the second signal, the broadband transformer circuit including,
first, second, and third lines, the first and second lines being electrically coupled to one another, the first and third lines being connected to an input of the broadband transformer circuit, the second line being connected to an output node of the broadband transformer circuit, the first and second lines being interconnected via the third line, the first, second and third lines each having an electrical length of a quarter wavelength, the input node of the broadband transformer circuit being connected to the combining node of the Doherty combiner circuit.

8. The dual band Doherty amplifier of claim 7, wherein the Doherty component circuit is configured such that, at both the first and second operating frequencies, during a power back-off operating state of the Doherty amplifier, if an impedance at the first input node is 50Ω,
the Doherty combiner circuit transforms the impedance at the first input node to 12.5Ω at the combining node, and
the impedance transformer circuit transforms the impedance at the combining node to 50Ω at the output of the impedance transformer circuit.

9. The dual band Doherty amplifier of claim 7, wherein the Doherty combiner circuit has a pi-type structure.

10. The dual band Doherty amplifier of claim 7, wherein the Doherty combiner circuit and the broadband impedance transformer circuit are each implemented using microstrip technology.

11. The dual band Doherty component circuit of claim 7, wherein the Doherty combiner circuit and the broadband impedance transformer circuit are each implemented using one or more of stripline technologies, coplanar technologies, waveguide technologies, and coax line technologies.
